(19) United States
(12) Patent Application Publication
(10) Pub. No.: US 2011/0216495 A1
(43) Pub. Date: Sep. 8, 2011

(54) DOCKING SYSTEM FOR ELECTRONIC DEVICES

(76) Inventor: Keith Bernard Marx, Richardson, TX (US)

(21) Appl. No.: 13/041,138

(22) Filed: Mar. 4, 2011

Related U.S. Application Data
(60) Provisional application No. 61/339,369, filed on Mar. 4, 2010.
(60) Provisional application No. 61/339,874, filed on Mar. 11, 2010.
(60) Provisional application No. 61/343,404, filed on Apr. 29, 2010.
(60) Provisional application No. 61/395,421, filed on May 13, 2010.
(60) Provisional application No. 61/402,797, filed on Sep. 7, 2010.

(51) Int. Cl. H05K 5/02

(52) U.S. Cl. 361/679.22

(57) ABSTRACT

A docking system is provided for docking one or more electronic devices. The docking system may include a docking platform, which may be a monitor. The docking platform may have docking receptacles for receiving the electronic devices. The electronic devices may include, for example, handheld or portable consumer electronic devices such as smart phones, gaming modules and laptops. A data exchange in the monitor provides electrical interconnectivity for the electronic devices and any internal or external peripheral devices. The various devices may communicate, and exchange data, with one another.

### CROSS-REFERENCE TO RELATED APPLICATION(S) AND CLAIM OF PRIORITY

The present application is related to U.S. Provisional Patent No. 61/339,369, filed Mar. 4, 2010, entitled “DOCKING MONITOR: A MONITOR WITH INTEGRATED DOCKING MECHANISM FOR PORTABLE SYSTEMS”. The present application hereby claims priority under 35 U.S.C. §119(e) to U.S. Provisional Patent No. 61/339,369. (2) The present application is related to U.S. Provisional Patent No. 61/339,874, filed Mar. 11, 2010, entitled “DOCKING MONITOR: A MONITOR SYSTEM WITH INTEGRATED DOCKING MECHANISM FOR PORTABLE DEVICES”. The present application hereby claims priority under 35 U.S.C. §119(e) to U.S. Provisional Patent No. 61/339,874. (3) The present application is related to U.S. Provisional Patent No. 61/343,404, filed Apr. 29, 2010, entitled “UNIVERSAL DOCKING MONITOR: A MONITOR WITH INTEGRATED DOCKING FEATURES FOR PORTABLE DEVICES”. The present application hereby claims priority under 35 U.S.C. §119(e) to U.S. Provisional Patent No. 61/343,404. (4) The present application is related to U.S. Provisional Patent No. 61/395,421, filed May 13, 2010, entitled “UNIVERSAL DOCKING MONITOR REV 4.0 A PLATFORM FOR INTEGRATED DOCKING FEATURES FOR PORTABLE DEVICES”. The present application hereby claims priority under 35U.S.C. §119(e) to U.S. Provisional Patent No. 61/395,421. (5) The present application is related to U.S. Provisional Patent No. 61/402,797, filed Sep. 7, 2010, entitled “DOCKING MONITOR REVISION 4A”. The present application hereby claims priority under 35 U.S.C. §119(e) to U.S. Provisional Patent No. 61/402,797.

### TECHNICAL FIELD

Various embodiments of the invention relate generally to electronic devices and, more particularly, to systems for docking multiple electronic devices on a common platform such as, for example, a monitor.

### BACKGROUND

A typical household has multiple electronic devices. These can include, for example, handheld, portable, and stationary electronic devices that are used for a variety of work, entertainment, and recreational purposes. Such devices may include, for example, mobile phones, cameras, desktop computers, laptop computers, notebook computers, Internet access devices, personal data assistants, televisions, video recorders, compact disc (CD) players, digital versatile disc (DVD) players, personal video game devices, video game stations, and the like. Typically, smaller devices, such as portable or handheld devices, have smaller user interfaces and displays in exchange for other factors such as ease of portability. While some devices are interoperable, many of the various devices have different connection hardware, software, and communication protocols. Certain devices may be connected by intermediate couplings such as, for example, USB cables. Some devices, such as certain laptop computer systems, have docking stations. The docking station may be used, for example, as a power source for the laptop and a connection point between the laptop and other computer peripherals such as a full-sized keyboard or a secondary monitor.

### SUMMARY

Currently, with respect to various consumer electronic devices, there is a need for the ability to merge the devices into a stationary platform with user interfaces and displays that are better than the user interfaces or displays of the individual devices. This is particularly true for smaller handheld and portable devices.

In one example embodiment, a docking system has a display device with a body. The body has an electronic display disposed thereon. The body further has at least one receptacle adapted to receive an information processing device. The docking system further has a first power and communication transfer mechanism in the display device adapted to connect to a second power and communication transfer mechanism in the information processing device in response to the information processing device being attached to the second surface. The display is adapted to display information associated with the information processing device.

In another example embodiment, a display apparatus has a body having an electronic display disposed thereon. The display apparatus also has at least one receptacle for receiving an information processing device and for electronically connecting the information processing device to the display.

### BRIEF DESCRIPTION OF THE DRAWINGS

For a more complete understanding of the present disclosure and its advantages, reference is now made to the following description taken in conjunction with the accompanying drawings, in which like reference numerals represent like parts:

FIG. 1 is a rear view of a docking system according to one example embodiment;

FIG. 2 is an isometric illustration of the docking system of FIG. 1 and showing a front of the docking system;

FIG. 3 is an illustration from a side view of the docking system of FIG. 1;

FIG. 4 is an illustration of a docking system according to another example embodiment and showing a particular example configuration of the keyboard;

FIG. 5 is an illustration of another example embodiment of a docking system;

FIG. 6 is an illustration of internal and external components of an example docking system;

FIG. 7 is an example of a docking system according to another embodiment and depicting and example user interface;

FIG. 8 is an illustration of an example docking system and depicting an integrated computer system;

FIG. 9 is an illustration of an example connection configuration for an example docking system;

FIG. 10 is an illustration of another example connection configuration for an example docking system;

FIG. 11 is an illustration depicting internal and external components of an example docking system; and

FIG. 12 is an illustration of another embodiment of an example docking system and depicting a removable display.

### DETAILED DESCRIPTION

Among other things, various embodiments of the present invention provide systems for docking various electronic devices. The docking systems of the various embodiments may have a number of different configurations. In at least some embodiments, a stationary device, or a device that is at least relatively permanently situated, such as a monitor, serves as the docking platform. The monitor may be, for example, a television monitor, such as might be mounted on a wall or set upon a piece of furniture in a household. The docking system provides, among other things, a centralized location for multiple electronic devices. The docked devices are accessed through the user interface and display of the centralized platform. Preferably, the centralized platform has a user interface and/or display that are superior to those of the docked devices. Superiority may be indicated by any number of predetermined criteria. For example, superiority of the display of a centralized docking platform may be indicated by a larger size than one or more of the devices being docked on the platform. The docked devices may be smaller, more portable devices, as compared to the centralized docking platform.

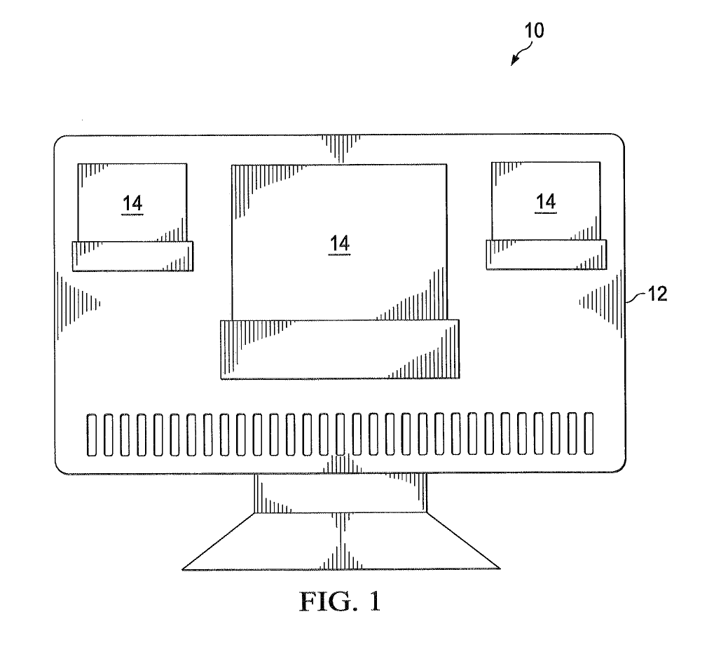

FIG. 1 illustrates one example embodiment of a docking system. A docking system 10 may comprise, for example, a docking platform 12. Preferably, docking platform 12 is a centralized platform in that it may receive, or dock, a plurality of different electronic devices 14. Docking platform 12 may comprise any number of different devices. In at least some embodiments, docking platform 12 is a monitor (as described, for example, herein). However, it should be understood that this is an example only, and docking platform 12 may comprise different types of monitors, as well as other types of devices.

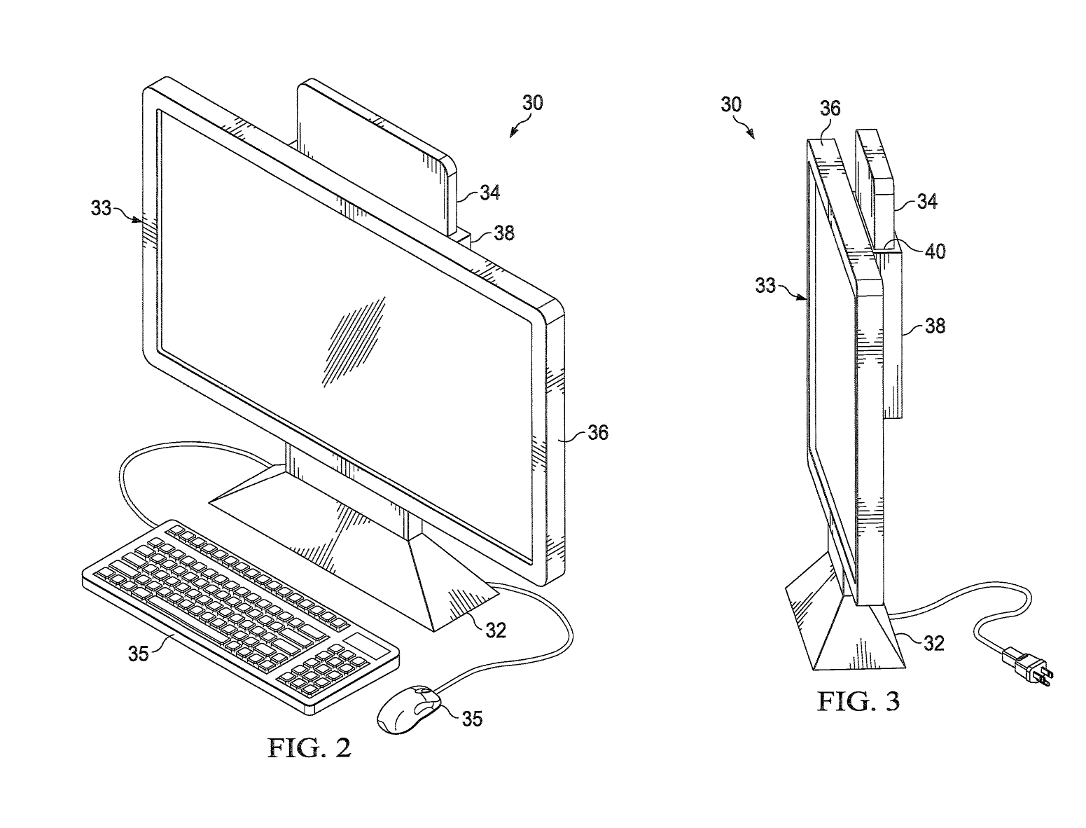

As shown in FIGS. 2 and 3, for example, a specific embodiment of a docking system 30 comprises a docking platform 32, which is a monitor 33. Docking monitor 33 is operable to receive at least one electronic device 34 for docking. For example, device 34 may comprise a laptop computer. Preferably, docking monitor 30 is operable to receive a plurality of electronic devices 34 (not expressly shown in FIGS. 2 and 3). Devices 34 may include, for example, any number of the more popular and powerful handheld and portable items such as mobile phones, cell phones, satellite phones, smart phones, personal digital assistants, netbooks, notebooks, laptops, handheld gaming devices, digital cameras, portable CD players, mp3 players, other media storage devices, and other items of similar nature. These devices may be referred to herein as Information Processing Devices (IPDs). However, it should be understood that this term is not intended to be limiting and at least some embodiments may also incorporate handheld devices, other non-digital devices, analog devices, devices that are not commonly portable, and/or any other device described herein or similar to those described herein.

Docking monitor 33 may comprise any suitable type of monitor. For example, docking monitor 33 may comprise a free-standing monitor as is commonly associated with desktop computing environments. Alternatively, docking monitor 33 may comprise a monitor that is integral with another device or computing platform. As yet another alternative, docking monitor 30 may comprise any type of conventional television monitor, such as a plasma screen monitor, liquid crystal device (LCD) monitor, digital signal processor (DSP) monitor, and the like. Preferably, docking monitor 33 has a housing 36, having one or more docking receptacles 38. Housing 36 provides, among other things, a structure to serve as a platform for docking devices 34.

A traditional “docking station” is a platform mainly found in the personal computer (PC) market and engineered to allow laptops to plug into a desktop computing environment. With this system, there is a containment box, or docking platform, into which the PC laptop slides or onto which the PC laptop is placed. The docking platform interfaces with peripheral devices, such as a monitor, that are connected to the docking platform. Another conventional docking station configuration, usually made for larger PC laptop systems, utilizes the monitor of the PC Laptop itself as the main monitor.

Interconnection from the PC laptop to the docking Station is accomplished via a plug-in connection usually residing in the side of the laptop. A normal work space incorporating a docking station has a monitor, a keyboard, and a mouse, together with the docking platform to hold the laptop. The interconnection between the docking platform and, for instance, the peripherals, is usually accomplished with a set of wired connections. Commonly, peripherals are connected to the docking platform with USB cables. Thus, there may be a separate USB cable for each peripheral. Moreover, if additional devices are brought into this desktop computing environment, they are typically connected (again by USB cables) to either the docking platform or to the laptop. For example, if a user wishes to connect a digital camera to the conventional docking system environment, the user will typically connect the camera, via a USB cable, to the laptop. Software operating on the laptop recognizes the connection of the camera and establishes the proper protocols necessary to make the camera work with the laptop, as well as with the peripherals connected to the docking platform.

Referring again to FIG. 1, among other things and as compared to conventional systems, docking system 10 reduces or eliminates the multiple, extra interconnects needed to connect the various peripherals to the docking platform. Also reduced or eliminated is the need for external cabling and the need for a separate device (e.g., in addition to the electronic devices) that serves as the docking platform itself.

In the case of the specific example illustrated in FIGS. 2 and 3, docking monitor 33 is a monitor with a docking receptacle 38 integrally incorporated into the back of the monitor housing 36. As shown, electronic device 34 is inserted into docking receptacle 38 on the back of docking monitor 33 where. According to at least some embodiments, receptacle 38 may comprise any suitable receptacle for fixedly coupling electronic device 34 to docking platform 32. As an illustrated example, docking receptacle 38 is a rectangular-shaped protrusion extending from a back surface of monitor 33. Receptacle 38 has a bottom surface, two opposite side surfaces and a distal surface, which is distal from, and parallel to, the rear surface of the monitor housing 36. The structure of receptacle 38 devices a cavity 40. Device 34 is inserted into cavity 40. Inside cavity 40, there are electrical connections (not expressly shown) to connect device 34 to monitor 33 so that device 34 may receive power, interact with platform 32, and interact with other devices 34 (not shown) that may be similarly docked on platform 32.

It should be understood that the particular configuration and placement of receptacle 38 illustrated in FIGS. 2 and 3 is an example only. In alternative embodiments, device 34 may be inserted into a side-facing, downward-facing, or rearward-facing receptacle. Also, receptacle 38 may be configured so that device 34 is pressed onto and/or snapped onto receptacle 38 (not expressly shown).

In at least one embodiment, all interconnections between monitor 33 and device 34 are done in a cable-free fashion. Device 34 is illustrated as being inserted from the top for easy access and also to allow the weight of device 34 to help in insertion of device 34 into receptacle 38. As discussed, however, device 34 may be inserted into, or otherwise coupled to, receptacle 38. It should be noted that there is no specific size requirement established for device 34 as docking monitor 33 can be designed for a specific dimension of device 34 or designed to support multiple classes of devices 34 (e.g., 14″ PC, PDA, smaller gaming device) each having a different dimension from the other.

Preferably, monitor 33 further comprises an ejection mechanism (not shown) for ejecting device 34 from receptacle 38. The ejection mechanism may have any number of configurations. For instance, the ejection mechanism may be purely mechanical with, for example, a lever to eject device 34 from receptacle 38. Alternatively, an embodiment may utilize an electro-mechanical solution (e.g., such as push buttons and solenoids). As another alternative, device 34 may be press fit onto monitor 33. Other coupling configurations may be utilized.

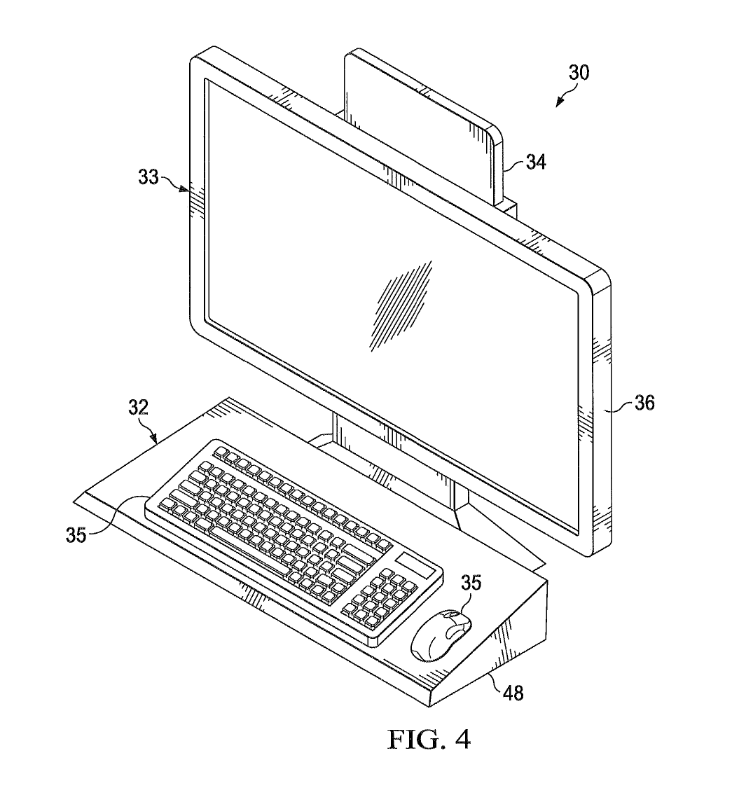

As shown in FIGS. 2 and 3, the system 30 may include one or more peripherals 35, such as a keyboard and a mouse. These may be coupled to platform 32 via cable or wireless connections. Alternatively, as illustrated in FIG. 4, a power pad 48 is coupled to platform 32, and the peripherals 35 are placed upon, or coupled to, power pad 48. Of course, other peripherals in addition to a keyboard and mouse may be connected to platform 32.

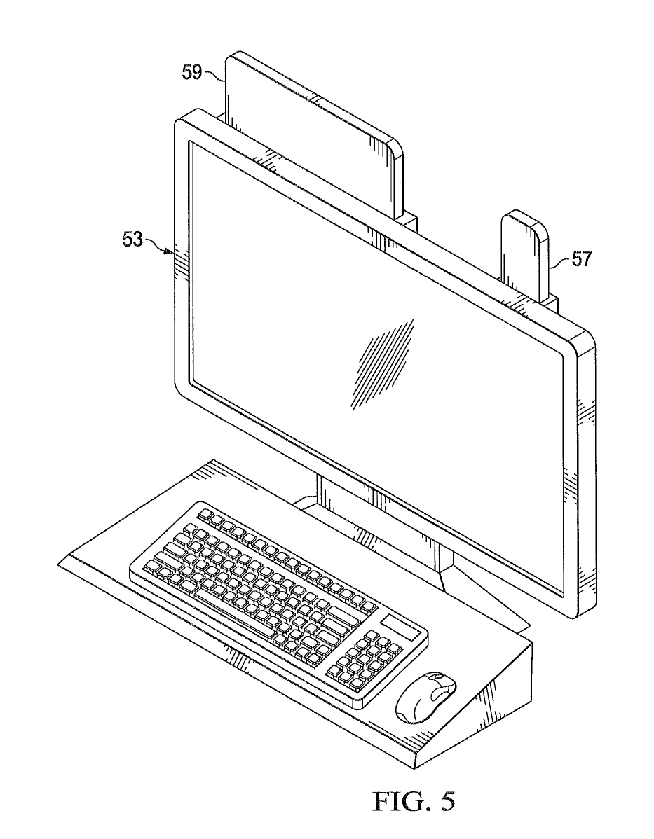

As noted, the platform may be configured to hold, or dock, more than one electronic device. As shown in FIG. 5, for example, a docking monitor 53 is shown supporting a plurality of electronic devices. The plurality of devices comprises a first electronic device 57 and a second electronic device 59. First electronic device 57 is a mobile phone and second electronic device 69 is a laptop computer. It should be noted that this is an example only, and the number of electronic devices may be more than two. Also, some of the plurality of electronic devices may be the same type of device, or different types of devices, such as a solid-state drive, television tuner, or video connect module Some of these devices may be viewed as devices that do not have full functionality independently from the monitor. Thus, in some instances, the combination of the docking monitor and the device results in the desired overall functionality. Particular configurations may depend on any number of factors, such as cost, complexity, space, and application requirements for a particular target market. Having more than a single electronic device docked on and interfacing with the docking platform allows connectivity between electronic devices and peripherals and thus a sharing of information and applications.

Electrical interconnection between multiple docked electrical devices, or between a given device and the docking platform or peripherals, can be accomplished by any suitable arrangement of hardware and/or software. The connections may be wired or wireless, for example. Preferably the interconnections are contained within the housing of the docking platform.

In at least one embodiment, the goal is to minimize the amount of interconnections. In certain cases, there are two sets of interconnections that need to be made. First, there are external interface connections (EICs) which can comprise an external power connection and one or more network connections. The network connections may include, for example, standard network protocols and/or video as part of the content. It should be noted that external data connections may come directly to the docking monitor or through devices coupled to the docking monitor. A second set of connections are the internal interface connections (IICs), which may comprise, for example, video interconnections, data interconnections, and power connections. It should be noted that the terms for “video,” “network,” or “data” are not intended to be limiting and the various interconnections can include any connections for any suitable purpose. These may include power delivery, charging, and interruption, media and content delivery, data transfer and storage, switching, etc.

For example, video may be transported over Network specific protocols such as Ethernet. Data normally considered “network data” can be transported over interfaces such as proprietary or off-the-shelf video interfaces, which may include hooks for embedded USB 2.0. When terms such as “data interconnections,” “video interconnections,” and “network interconnections” are used herein, it is assumed that the primary transport content is what is being considered, but the terms are not limited only to their respective types of information.

External interface connections for power and networks can be handled in any number of suitable multiple ways. A first example configuration utilizes a standard power connection to an ordinary wall socket (e.g., in the U.S. this would be 60 Hz, 110V). A network connection can be accomplished with standard wired connection schemes such as a wireline Ethernet. As an alternative, a connection may utilize a standard wall socket connection, but with optional wireless connectivity such as Wifi allowing for only one cable connection to the external environment.

An alternative approach involves providing a wireline-based network connection that embeds the power source through the cable. An example of this would be “power over Ethernet.”

Internal interface connections may involve, as an example, two interconnection points. A first interconnection is established between a docked electronic device and the docking platform itself. Preferably, this is accomplished using a physical connection mechanism through a connector. The connection may also be made via a cable. Preferably, power, video, and data communications are incorporated into this internal interface (e.g., 12VDC USB interconnections). A second internal interface connection is for user interface devices (e.g., keyboard and mouse) or other peripherals. These components can be interconnected using standard wireline based techniques (e.g., USB) or can be accomplished using wireless techniques.

FIG. 2 illustrates a docking monitor with wired connections between the main system and various user interface devices. FIG. 5 illustrates a completely wireless approach for the user interface devices. In this approach the keyboard and mouse have several wireless interface components. A first component is a wireless data interconnect via any suitable hardware and/or software components, such as Bluetooth. A second component is a power charging mechanism via radio frequency (RF) power transfer incorporated into the base of the docking monitor.

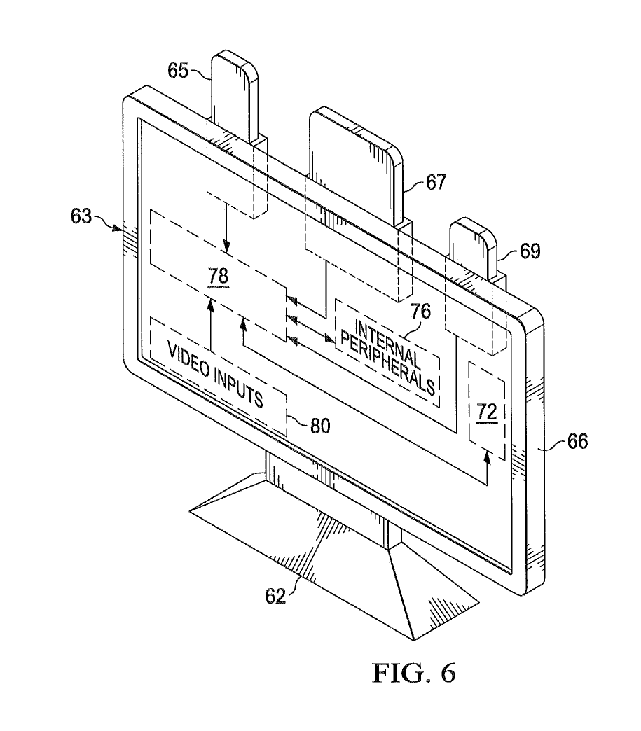

FIG. 6 illustrates another example embodiment of an interconnection scheme linking video and data streams between docked electronic devices and internal and external peripherals. A docking platform 62 comprises a docking monitor 63 having a housing 66. The housing has a number of docking receptacles that are integral to the housing. In other words, the docking receptacles do not protrude from a surface of docking monitor 63. The docking receptacles are shown supporting first, second, and third electronic devices 65, 67, and 69. In this example, first electronic device 65 is a tuner or remote control, second electronic device 67 is a netbook, and third electronic device 69 is a personal data assistant (PDA), or a smart phone or other similar device.

The illustrated system comprises a data exchange 78 to interconnect all devices to a central video processing function that passes video to the monitor and also links all other devices within the system. As shown, tuner 65 is connected to data exchange 78. Likewise, netbook 67 and PDA 69 (or smart phone or other similar device) are connected to data exchange 78. Data exchange 78 is connected to external connection bus 72 and to one or more internal peripherals 76. Video input device 80 is also coupled to data switch 78. The specific interconnection scheme is not limited to the illustrated configuration and those having ordinary skill in the art will appreciate that any suitable interconnection configuration may be utilized.

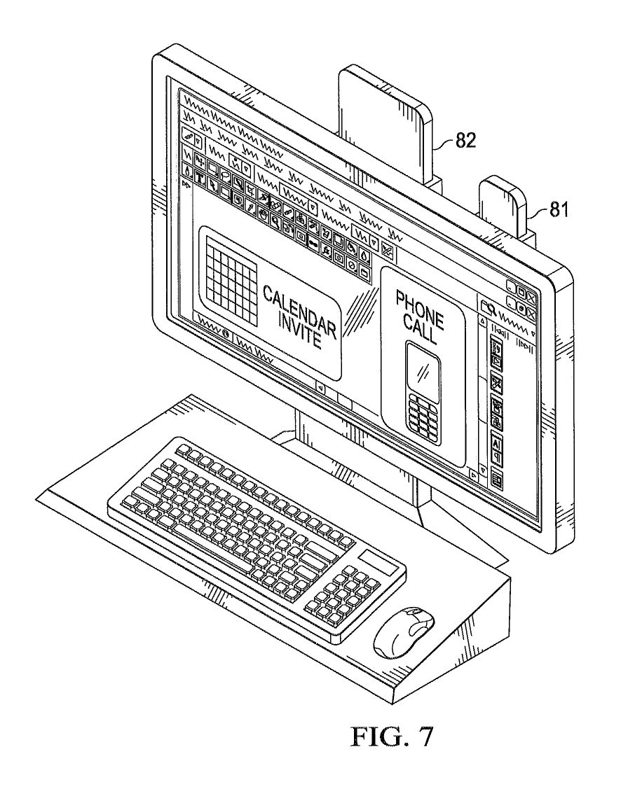

Establishing a data link between the electronic devices as mentioned previously enables the system to integrate functionality and applications from each of the independent devices. FIG. 7 illustrates this integrated functionality in that a smart phone 81 and a netbook 82 communicate to coordinate phone and contact information minimizing the user's need to monitor and interface with both devices.

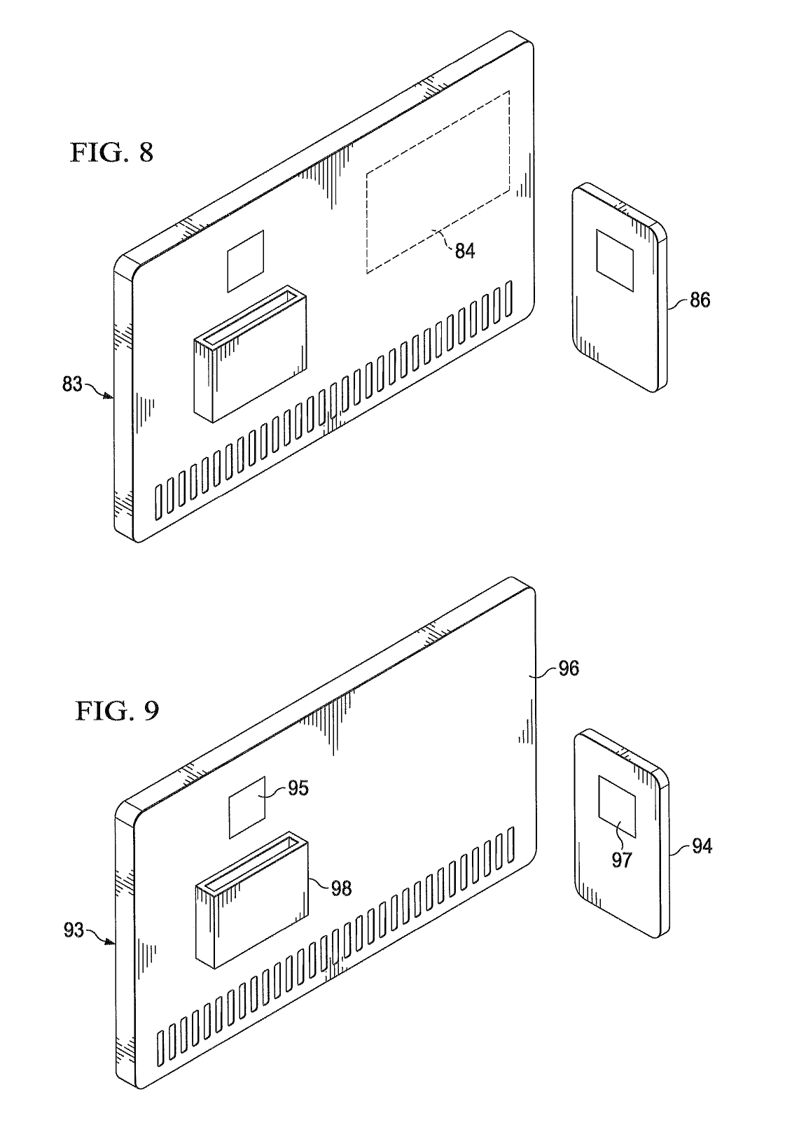

In at least one embodiment, the docking monitor is not limited to a display with no complex computing functionality. As illustrated in FIG. 8, a docking monitor 83 includes an integrated computer system 84. An example of the integrated computer system 84 is a stand-alone integrated personal computer system that has a PC system and a monitor integrated into one unit, but that also has a provision for one or more docked electronic devices 86.

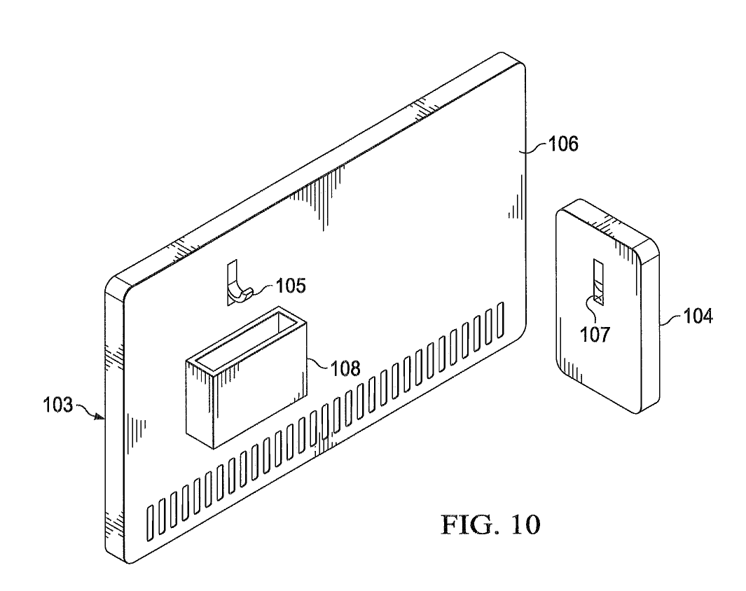

FIGS. 9 and 10 illustrate two methods for supplemental mounting of electronic devices to a docking monitor. As illustrated in FIG. 9, for example, an electronic device 94 may be docked in a docking receptacle 98, which is integral with, or coupled to, a rear surface of housing 96 of docking monitor 93. A mechanical supplemental mounting system comprises a first magnetic portion 95 on the rear surface of housing 96 and a second magnetic portion 97 on electronic device 94. The first and second magnetic portions 95, 97 are configured to be aligned when electronic device 94 is docked in receptacle 98. First and second magnetic portions 95, 97 interact in an attracting manner to hold electronic device 94 onto the rear surface of housing 96 of docking monitor 93.

As illustrated in FIG. 10 a hook and slot arrangement is provided for supplemental support. An electronic device 104 may be docked in a docking receptacle 108, which is integral with, or coupled to, a rear surface of housing 106 of docking monitor 103. A mechanical supplemental mounting system comprises a hook 105 on the rear surface of housing 106 and a slot 107 formed in a surface of electronic device 104. The hook 105 and slot 107 are configured to be aligned when electronic device 104 is docked in receptacle 108. Hook 105 and slot 107 interact to hold electronic device 104 onto the rear surface of housing 106 of docking monitor 103. It should be noted that this is an example connection technique and the disclosure is not limited to this technique.

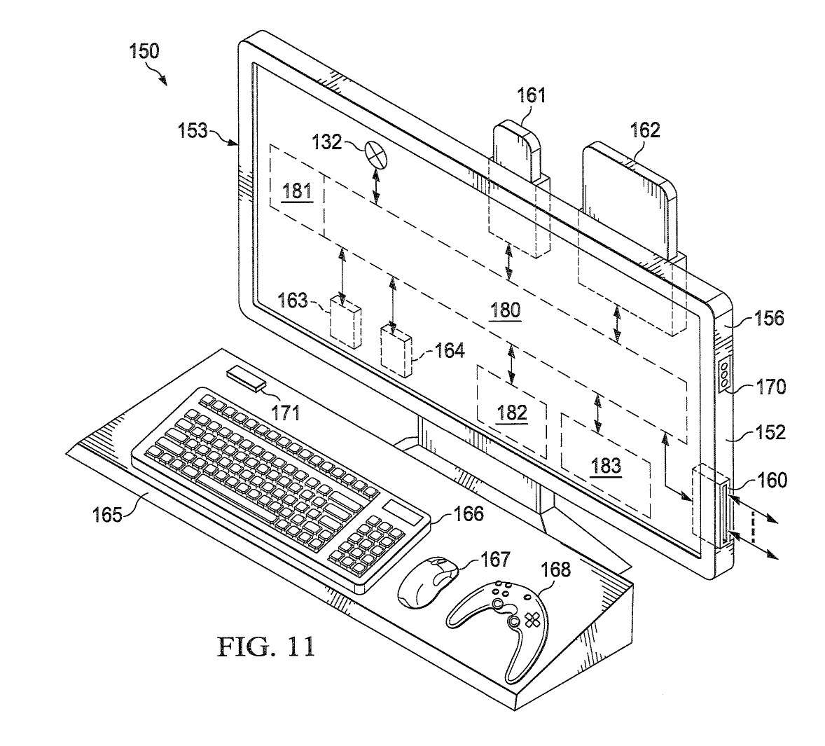

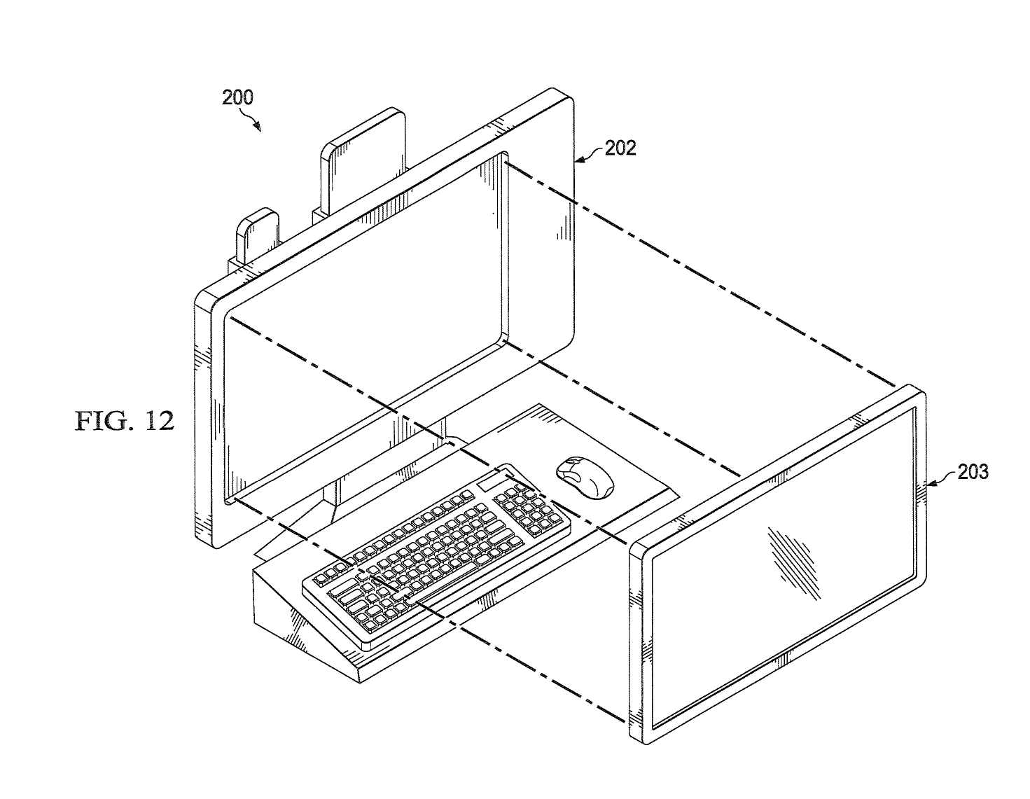

Certain other example embodiments are illustrated in FIG. 11. As illustrated, for example, a docking system 150 comprises a docking platform 152. Docking platform 152 may be a docking monitor 153 having a housing 156. As illustrated, various electronic devices are docked on docking monitor 153. These include smart phone 161, laptop 162, video input module 163, solid state drive 164, game module 170, and personal data assistant 171. These devices are examples only.

System 150 also includes a power pad 165 and certain external peripherals such as a keyboard 166, a mouse 167, and a gaming controller 168. System 150 also includes one or more internal peripherals 183 and an external connection port 160.

The electronic devices may be coupled, or docked, to docking monitor 153 by any of the methods described herein. Thus, the electronic devices may be coupled by mechanical or electromechanical connections, docking receptacles, etc. The coupling may be achieved at any of the various positions in or on the housing such as, for example, on the rear surface, top surface, or side surface, as illustrated. The electronic devices may reside in the same plane as the docking monitor (as with, for example, the smart phone and laptop) or in a different plane (as with, for example, the game module). One or more of the various electronic devices, such as personal data assistant 171, may reside on, or be docked on, power pad 165.

Certain devices such as, for example, the solid state drive and the video input module, may be provided as application modules rather than internal or external peripheral devices. Further, an internal computing platform 183 may be provided and is connected to data exchange 180.

Circuitry within docking monitor 153 provides a data exchange 180 and connections to the various components including, without limitation, the various docked electronic devices and external and internal peripherals. A control processor 181 is provided for controlling the various connections and interactivity between the various components. Also connected to data exchange 180 is a video module 182 for providing video from any of the various devices to the display (not expressly shown) of docking monitor 153.

In at least one embodiment, a display is a separate component that is coupled to the docking platform. As shown in FIG. 12, for example, a docking system 200 includes a docking platform 202. A display 203, such as a tablet, is coupled to the platform 202. Preferably, the display is docked on the platform and electrically connected to the other various components through an internal data exchange as previously described.

Although the present disclosure has been described with an exemplary embodiment, various changes and modifications may be suggested to one skilled in the art. It is intended that the present disclosure encompass such changes and modifications as fall within the scope of the appended claims.

What is claimed is:

1. A docking system comprising:
a display device having a body, the body having an electronic display disposed thereon, the body further having at least one receptacle adapted to receive an information processing device; and
a first power and communication transfer mechanism in the display device adapted to connect to a second power and communication transfer mechanism in the information processing device in response to the information processing device being attached to the second surface, the display being adapted to display information associated with the information processing device.

2. The docking system of claim 1, wherein the at least one receptacle comprises a plurality of receptacles, each of the plurality of receptacles being adapted to receive an information processing device.

3. The docking system of claim 1, further comprising a personal computing platform integrated into the display device, the personal computing platform operable to be electronically connected to the information processing device.

4. The docking system of claim 1, wherein the information processing device comprises a mobile phone.

5. The docking system of claim 1, wherein the information processing device comprises a portable computer.

6. The docking system of claim 1, wherein the information processing device comprises a audio device.

7. The docking system of claim 1, wherein the information processing device comprises a media storage device.

8. The docking system of claim 1, wherein the information processing device comprises a camera.

9. The docking system of claim 1, wherein the at least one receptacle comprises a cavity integral with the body, the cavity having an opening for receiving the information processing device.

10. The docking system of claim 9, wherein the at least one receptacle comprises a pair of side portions integral with and extending from a surface of the body, a bottom portion coupled to the pair of side portions, the bottom portion being integral with and extending from the surface of the body, and a distal portion coupled to the pair of side portions and the bottom portion;
wherein an upper part of the side portions and the distal portion form an opening, the cavity extending from the opening to the bottom portion.

11. The docking system of claim 1, wherein the connection between the first and second power and communication transfer mechanisms is a cable-free connection.

12. The docking system of claim 1, wherein the at least one receptacle has an opening proximal an upper surface of the body, and wherein the receptacle has a cavity extending downward from the opening.

13. The docking system of claim 1, further comprising an ejection mechanism adapted to eject the information processing device from the at least one receptacle.

14. The docking system of claim 1, wherein the connection between the first and second power and communication transfer mechanisms comprises an external interface connection.

15. The docking system of claim 1, wherein the connection between the first and second power and communication transfer mechanisms is operable to deliver power from the display device to the information processing device.

16. The docking system of claim 1, wherein the connection between the first and second power and communication transfer mechanisms is operable to charge the information processing device.

17. The docking system of claim 1, wherein the connection between the first and second power and communication transfer mechanisms provides a data transfer path for transferring data from the information processing device to the display device.

18. The docking system of claim 1, wherein the connection between the first and second power and communication transfer mechanisms comprises a network connection.

19. The docking system of claim 1, further comprising a central data exchange disposed within the body of the display device and wherein the information processing device and the display are coupled electronically coupled to the central data exchange to permit transfer of data between the information processing device and the display.

20. A display apparatus comprising:
a body having an electronic display disposed thereon; and
at least one receptacle for receiving an information processing device and for electronically connecting the information processing device to the display.

21. The display apparatus of claim 20 further comprising a user interface operable to allow a user to access information from the information processing device.

22. The display apparatus of claim 20, wherein the electronic connection between the information processing device and the display provides power transfer from the display apparatus to the information processing device and data transfer from the information processing device to the display apparatus.
